(19) United States
(12) Patent Application Publication
(10) Pub. No.: US 2005/0233516 A1
(43) Pub. Date: Oct. 20, 2005

(54) Semiconductor device and manufacturing method thereof

(75) Inventors: Hidenori Iwadate, Hyogo (JP); Hitoshi Kuriyama, Osaka (JP); Masao Yoshizawa, Toyama (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/095,529

(22) Filed: Apr. 1, 2005

(30) Foreign Application Priority Data
Apr. 14, 2004 (JP) P2004-118940

(51) Int. Cl. H01L 21/8238

(52) U.S. Cl. 438/202

(57) ABSTRACT

In a semiconductor device according to the present invention, an emitter diffusion layer is formed with a polycrystal silison emitter layer serving as a diffusion source, and an impurity concentration of the polycrystal silicon emitter layer is higher than an impurity concentration of the emitter diffusion layer, wherein the emitter diffusion layer is of a shallow junction and an emitter impurity concentration is increased.

### BACKGROUND OF THE INVENTION

1. Field of the Invention

The present invention relates to a semiconductor device and a method of manufacturing the semiconductor, more particularly to a semiconductor device provided with a polycrystal silicon emitter layer and a method of manufacturing the semiconductor device.

2. Description of the Related Art

In recent years, a higher speed has been increasingly advanced in a semiconductor integrated circuit, in response to which it is now demanded that a bipolar transistor be operated in a high-frequency region by downsizing elements, and also, a current amplification factor be increased. In order to do so, it becomes necessary to promote a shallow junction and a high density in a base diffusion layer, and further, to reduce a resistance of an emitter layer. To respond to the demand, a semiconductor device in which an emitter electrode and a base electrode are formed in a self-aligning structure has been proposed and made commercially available.

In a semiconductor device having a BiCMOS structure in which the bipolar transistor and CMOS transistor are formed on the same semiconductor substrate, in particular, it is demanded that the current amplification factor of the bipolar transistor be increased without undermining a characteristic of the CMOS transistor. For that purpose, an emitter diffusion layer of the bipolar transistor and a source/drain diffusion layer of the MOS transistor are independently formed so that an emitter impurity concentration is increased.

However, the current amplification factor is determined based on a ratio obtained by comparing the emitter and base impurity concentrations, which makes it necessary to increase the impurity concentration of a polycrystal silicon emitter layer in order to increase the current amplification factor. When the diffusion layer is formed by means of solid phase diffusion, the impurity concentration of the solid phase and the impurity concentration of the surface of the impurity diffusion layer are equal to each other, and a diffusion depth is increased as the impurity concentration of the solid phase is higher. The depth of the emitter diffusion layer increases as the impurity concentration of the polycrystal silicon emitter layer becomes higher because the emitter diffusion layer is formed from the diffusion of the impurities of the polycrystal silicon emitter layer. The shallow junction of the base diffusion layer in order to enable the operation in the high-frequency region results in the reduction of a base width because the current amplification factor is increased.

On the contrary, the emitter diffusion layer has to be shallowed in order to increase Early voltage and an emitter/collector withstand voltage. It is possible to increase the current amplification factor by raising the impurity concentration of the polycrystal silicon emitter layer, in which case, however, the Early voltage and the emitter/collector withstand voltage are disadvantageously lowered as a result of the deepened diffusion.

The Early voltage is described here. A phenomenon generated in the transistor characteristic when a width of a neutral base region fluctuates because a depletion layer in the base/collector junction fluctuates in response to an inconstant collector voltage in a high injection region of a large current in the bipolar transistor is called the Early effect. In the case of an NPN transistor, the collector depletion layer expands to the base side in compliance with the increase of a collector/emitter voltage as a base current increases thereby extending an effective base length, as a result of which the current amplification factor is increased and the collector current is correspondingly increased. The Early voltage is an absolute value of a V_{CE} value (negative value) when a characteristic curve is extended and I_{C} becomes zero in the V_{CE}-I_{C} characteristic. Preferably, the larger the Early voltage is, the smaller the fluctuation of I_{C} is.

As described, the characteristic of the current amplification factor and the characteristic of the Early voltage are in a trade-off relationship, which makes it difficult to improve both of the characteristics of the current amplification factor and the Early voltage. In particular, in the case of a bipolar transistor of PNP type, the foregoing disadvantage is even more remarkable because the emitter diffusion layer is formed through the solid phase diffusion using boron having a large diffusion coefficient.

### BRIEF SUMMARY OF THE INVENTION

A semiconductor device according to the present invention comprises:
a collector diffusion layer formed in a semiconductor substrate;
a base diffusion layer formed in the collector diffusion layer;
an emitter diffusion layer formed in the base diffusion layer; and
a polycrystal silicon emitter layer formed on the emitter diffusion layer and having an impurity concentration higher than an impurity concentration of a surface of the emitter diffusion layer.

According to the foregoing constitution, the emitter diffusion layer can be shallow while the impurity concentration of the emitter diffusion layer is high. Accordingly, a high-performance semiconductor device capable of controlling the reduction of a base width, preventing the reduction of the Early voltage and emitter/collector withstand voltage and obtaining a high current amplification factor can be realized.

Further, a semiconductor device according to the present invention is a semiconductor device of a BiCMOS structure having a bipolar transistor and a MOS transistor. In the semiconductor device, the bipolar transistor comprises:
a collector diffusion layer formed in a semiconductor substrate;
a base diffusion layer formed in the collector diffusion layer;
an emitter diffusion layer formed in the base diffusion layer; and
a polycrystal silicon emitter layer formed on the emitter diffusion layer and having an impurity concentration higher than an impurity concentration of a surface of the emitter diffusion layer.

The CMOS transistor comprises:
a well layer formed in the semiconductor substrate;
a polycrystal silicon gate electrode formed on the well layer via a gate insulation film; and
a source/drain diffusion layer formed in the well layer.

An emitter impurity concentration obtained by summing the impurity concentration of the polycrystal silicon emitter layer and the impurity concentration of the emitter diffusion layer is higher than an impurity concentration of the source/drain diffusion layer.

According to the foregoing constitution, the characteristic of the MOS transistor and the characteristic of the bipolar transistor are independent from each other because the impurity concentration of the source/drain diffusion layer in the MOS transistor and the emitter impurity concentration are different to each other. Therefore, the high-performance semiconductor device of the BiCMOS structure capable of obtaining a high current amplification factor without undermining the characteristic of the MOS transistor and reducing the Early voltage and the emitter/collector withstand voltage in the bipolar transistor can be provided.

In the foregoing semiconductor device, the polycrystal silicon emitter layer is preferably a diffusion source of the impurities of the emitter diffusion layer.

In the foregoing semiconductor device, the bipolar transistor preferably further comprises an external base diffusion layer formed in a periphery of the base diffusion layer and a polycrystal silicon external base layer connected to the external base diffusion layer, wherein an impurity concentration of the polycrystal silicon external base layer is equal to an impurity concentration of the polycrystal silicon gate electrode, and the polycrystal silicon external base layer is preferably a diffusion source of the impurities of the base diffusion layer.

According to the foregoing constitution, the characteristic of the bipolar transistor and the characteristic of the MOS transistor are independent from each other. Therefore, the high-performance semiconductor device of the BiCMOS structure capable of obtaining a high current amplification factor without undermining the characteristic of the MOS transistor and reducing the Early voltage and the emitter/collector withstanding voltage in the bipolar transistor can be provided. As a further advantage, the impurities can be additionally introduced into the polycrystal silicon emitter layer at the same time as the formation of the source/drain diffusion layer of the MOS transistor. As a result, the high-performance bipolar transistor of a self-aligning type can be formed without increasing a manufacturing cost.

A method of manufacturing a semiconductor device according to the present invention comprises:
a step of forming a collector diffusion layer in a semiconductor substrate;
a step of forming a base diffusion layer in the collector diffusion layer;
a step of forming a polycrystal silicon emitter layer serving as a diffusion source of impurities on the base diffusion layer;
a step of forming an emitter diffusion layer by diffusing the impurities of the polycrystal silicon emitter layer in the base diffusion layer; and
a step of additionally introducing the impurities into the polycrystal silicon emitter layer and applying a heat treatment to the impurities at a temperature lower than a diffusion temperature at which the emitter diffusion layer is formed to thereby activate the impurities.

According to the foregoing manufacturing method, the polycrystal silicon emitter layer is used as the diffusion source so as to form the emitter diffusion layer, and the impurities are additionally introduced into the polycrystal silicon emitter layer and activated at a temperature lower than the temperature at which the emitter diffusion layer is formed after the formation of the emitter diffusion layer. As a result, the concentration of the impurities additionally introduced into the polycrystal silicon emitter layer can be adjusted. Further, the emitter impurity concentration can be increased without changing the depth of the emitter diffusion layer, and the current amplification factor can be easily controlled separately from the Early voltage and the emitter/collector withstand voltage, which realizes a high current amplification factor.

Further, a method of manufacturing a semiconductor device having a BiCMOS structure according to the present invention comprises:
a step of forming a collector diffusion layer and a well layer in a semiconductor substrate;
a step of forming a polycrystal silicon gate electrode on the well layer via a gate insulation film;
a step of forming a base diffusion layer in the collector diffusion layer;
a step of forming a polycrystal silicon emitter layer serving as a diffusion source of impurities on the base diffusion layer;
a step of forming an emitter diffusion layer by diffusing the impurities of the polycrystal silicon emitter layer in the base diffusion layer;
a step of additionally introducing the impurities into the polycrystal silicon emitter layer;
a step of introducing the impurities into the well layer; and
a step of applying a heat treatment to the impurities at a temperature lower than a diffusion temperature at which the emitter diffusion layer is formed to thereby form a source/drain diffusion layer in the well layer and activate the impurities of the polycrystal silicon emitter layer.

According to the foregoing manufacturing method, the emitter diffusion layer is formed separately from the source/drain diffusion layer of the MOS transistor. Therefore, the high-performance semiconductor device capable of obtaining a high current amplification factor without undermining the characteristic of the MOS transistor and reducing the Early voltage an the emitter/collector withstand voltage in the bipolar transistor can be realized.

In the foregoing method of manufacturing the semiconductor device, the step of additionally introducing the impurities into the polycrystal silicon emitter layer is preferably carried out at the same time as the step of introducing the impurities into the well layer. The high-performance bipolar transistor of the self-aligning type can be formed without increasing the manufacturing cost as a result of additionally introducing the impurities into the source/drain diffusion layer of the MOS transistor at the same time as the formation of the polycrystal silicon emitter.

In the foregoing method of manufacturing the semiconductor device, it is preferable that a step of forming a field insulation film prior to the formation of the polycrystal silicon gate electrode be further comprised, the step of forming the polycrystal silicon gate electrode include a step of simultaneously forming a polycrystal silicon external base layer having an opening on the collector diffusion layer on the field insulation film and on the collector diffusion layer to thereby form an external base diffusion layer by diffusing the impurities of the polycrystal silicon external base layer in the collector diffusion layer after the formation of the polycrystal silicon external base layer, and the base diffusion layer be formed in the collector diffusion layer via the opening in the step of forming the base diffusion layer.

In the foregoing method of manufacturing the semiconductor device, the step of forming the emitter diffusion layer is preferably carried out at a high temperature and in a short period of time by means of a lamp annealing treatment.

Additional objects of the invention will be apparent from the following detailed description of preferred embodiments thereof, which are best understood with reference to the accompanying drawings.

### BRIEF DESCRIPTION OF THE DRAWINGS

FIG. 1 is a sectional view of a semiconductor device according to an embodiment 1 of the present invention.

FIG. 2 is a distribution chart of an impurity concentration of A-A′ part in FIG. 1.

FIGS. 3A-3E are sectional views of respective steps in a method of manufacturing the semiconductor device according to the embodiment 1.

FIG. 4 is a sectional view of a semiconductor device according to an embodiment 2 of the present invention.

FIGS. 5A-5D are sectional views of respective steps in a method of manufacturing the semiconductor device according to the embodiment 2.

FIGS. 6A-6C are sectional views of respective steps in the method of manufacturing the semiconductor device according to the embodiment 2 (continued from FIG. 5).

FIGS. 7A-7D are sectional views of respective steps in a method of manufacturing a semiconductor device according to an embodiment 3 of the present invention.

FIGS. 8A-8C are sectional views of respective steps in the method of manufacturing the semiconductor device according to the embodiment 3 (continued from FIG. 7).

In all these figures, like components are indicated by the same numerals

### DETAILED DESCRIPTION OF THE PREFERRED EMBODIMENTS

Hereinafter, preferred embodiments of a semiconductor device according to the present invention are described referring to the drawings.

### EMBODIMENT 1

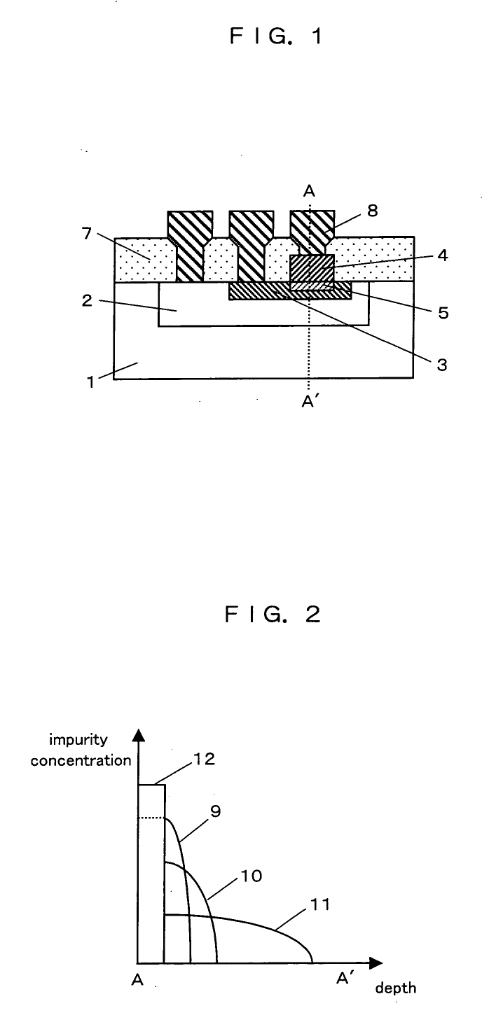

FIG. 1 is a sectional view of a semiconductor device of a bipolar structure having a bipolar transistor of PNP type according to an embodiment 1 of the present invention. FIG. 2 is a distribution chart of an impurity concentration of A-A′ part in FIG. 1.

As shown in FIG. 1, a P-type collector diffusion layer 2 is formed in a semiconductor substrate 1, an N-type base diffusion layer 3 is formed in the P-type collector diffusion layer 2, and a P-type emitter diffusion layer 5 is formed in the base diffusion layer 3 using a polycrystal silicon emitter layer 4 including boron as a diffusion source. Further, an insulation film 7 is deposited on the respective diffusion layers, and the respective diffusion layers are connected to wirings 8 via contact holes.

Referring to reference numerals in FIG. 2, 9 denotes a distribution of a P-type impurity concentration of the emitter diffusion layer, 10 denotes a distribution of an N-type impurity concentration of the base diffusion layer 3, 11 denotes a distribution of a P-type impurity concentration of the collector diffusion layer 2, and 12 denotes a distribution of a P-type impurity concentration of the polycrystal silicon emitter layer 4. In the case of the solid phase diffusion, the impurity concentration of the diffusion layer surface and the impurity concentration of the solid phase are generally equal to each other. However, in the present embodiment, the impurity concentration 12 of the polycrystal silicon emitter layer 4 is higher than the impurity concentration 9 of a surface of the emitter diffusion layer 5. An emitter impurity concentration in the foregoing case is represented by the sum of the impurity concentration 9 of the emitter diffusion layer 5 and the impurity concentration 12 of the polycrystal silicon emitter layer 4, and takes a value larger than the impurity concentration 10 of the base diffusion layer 3.

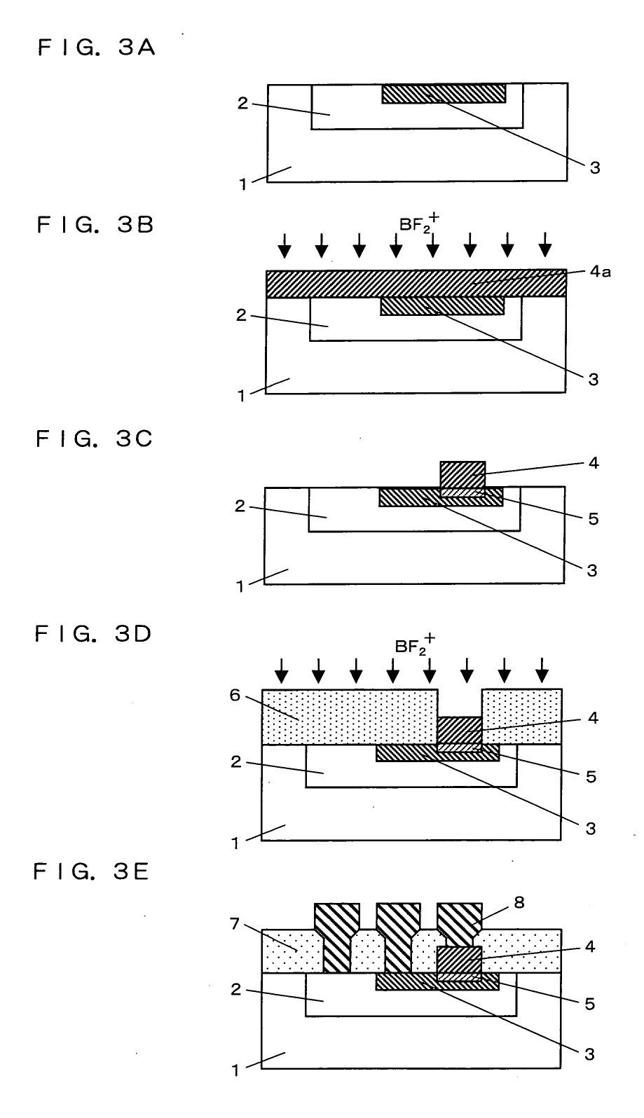

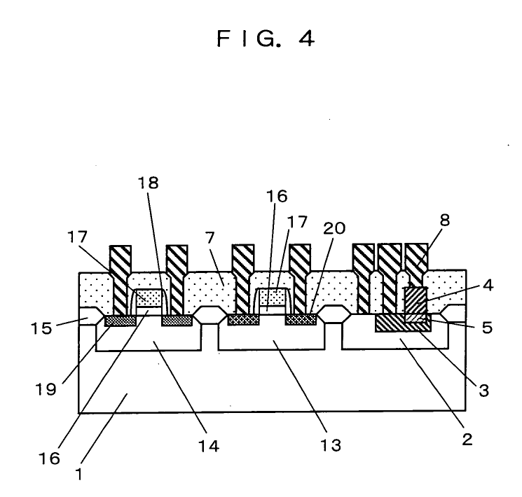

Next, respective steps in a method of manufacturing the semiconductor device according to the present embodiment are described referring to sectional views in FIGS. 3A-3E.

First, as shown in FIG. 3A, the P-type collector diffusion layer 2 is formed in the semiconductor substrate 1 having an N-type epitaxial layer on a surface thereof by ion-implanting P-type impurities (for example, boron). After that, N-type impurities (for example, phosphorous) are ion-implanted in the collector diffusion layer 2 at, for example, an accelerating energy of 45-55 keV and a dosage of 3-5×10¹³ cm⁻² so as to form the N-type base diffusion layer 3.

Next, as shown in FIG. 3B, a polycrystal silicon film 4a having a thickness of approximately 200 nm is grown on an entire surface of the substrate, and BF₂⁺ is ion-implanted at, for example, an acceleration energy of 25-35 keV and a dosage of 3-8×10¹⁵ cm⁻².

Next, as shown in FIG. 3C, the polycrystal silicon emitter layer 4 including boron is formed at a predetermined position by means of a photo-resist patterning process, and further, a dry etching process. Then, a heat treatment is applied at a temperature, for example, in the range of 900-1000° C. so as to diffuse boron in the base diffusion layer 3 using the polycrystal silicon emitter layer 4 as the diffusion source so that the P-tyep emitter diffusion layer 5 is formed.

Next, as shown in FIG. 3D, a photo resist 6 is patternized, and BF₂⁺ is ion-implanted in the polycrystal silicon emitter layer 4 at, for example, an acceleration energy of 25-35 keV and a dosage of 3-8×10¹⁵ cm⁻². After that, the heat treatment is applied at a temperature lower than the heat-treatment temperature at which the emitter diffusion layer 5 is formed (900-1000° C.), for example, in the range of 800-900° C. In the foregoing step, boron is introduced into the polycrystal silicon emitter layer 4 again after the emitter diffusion layer 5 is formed, however, the heat-treatment temperature is lower than the temperature at which the emitter diffusion layer 5 is formed, which causes very little influence to a depth of the emitter diffusion layer S. No particular value is provided for a ratio of the impurity concentration in the formation of the emitter diffusion layer 5 to the concentration of the added impurities, which is allowed to be determined in accordance with a desired transistor characteristic.

Next, as shown in FIG. 3E, after the insulation film 7 is deposited on the respective diffusion layers and the polycrystal silicon emitter layer 4, the contact holes are opened and the wirings 8 are formed.

As described, according to the present embodiment, the emitter diffusion layer 5 is formed with the polycrystal silicon emitter layer 4 as the diffusion source, and thereafter the impurities are introduced into the polycrystal silicon emitter layer 4 again. However, the emitter impurity concentration can be increased with very little influence to the depth of the emitter diffusion layer 5 because the added impurities are activated at the temperature lower than the heat-treatment temperature in the emitter formation. Thereby, an effective base width can be prevented from decreasing, and further, the Early voltage and emitter/collector withstand voltage can be prevented from lowering, while a high current amplification factor can be realized

Moreover, when the lamp annealing treatment is used for the heat treatment for the formation of the emitter diffusion layer 5, the heat treatment can be implemented at a higher temperature and in a shorter period of time. In such a manner, the emitter diffusion layer 5 can be formed continuously preventing any influence on the distribution of the impurity concentration of the base diffusion layer 3. Further, the emitter diffusion layer 5 hardly likely to receive any influence from the heat treatment for activating the impurities, which are later additionally introduced into the polycrystal silicon emitter layer 4, can be formed.

### Embodiment 2

FIG. 4 is a sectional view of a semiconductor device of a BiCMOS structure having a PNP-type bipolar transistor and a CMOS transistor according to an embodiment 2 of the present invention.

As shown in FIG. 4, a P-type collector diffusion layer 2 is formed in a semiconductor substrate 1, an N-type base diffusion layer 3 is formed in the P-type collector diffusion layer 2, and a P-type emitter diffusion layer 5 is formed in the base diffusion layer 3 using a polycrystal silicon emitter layer 4 including boron as a diffusion source. Referring to PMOS and NMOS transistors, a polycrystal silicon gate electrode 17 including phosphorous P is formed on an N-type well layer 13 and a P-type well layer 14 via a gate insulation film 16, and a P-type source/drain diffusion layer 20 and an N-type source/drain diffusion layer 19 are respectively formed in the N-type well layer 13 and P-type well layer 14. An insulation film 7 is deposited on the respective diffusion layers, and the respective diffusion layers are connected to wirings 8 via contact holes. A reference numeral 15 denotes a field oxide film for element isolation, and a reference numeral 18 denotes a side wall of the silicon gate electrode 17.

The polycrystal silicon gate electrode 17 of the MOS transistor and the polycrystal silicon emitter layer 4 of the bipolar transistor are each a different polycrystal silicon. An impurity concentration of the polycrystal silicon emitter layer 4 is higher than an impurity concentration of a surface of the emitter diffusion layer 5, and further, an emitter impurity concentration obtained by summing the impurity concentration of the polycrystal silicon emitter layer 4 and the impurity concentration of the emitter diffusion layer 5 is higher than an impurity concentration of the source/drain diffusion layer 20 of the PMOS transistor.

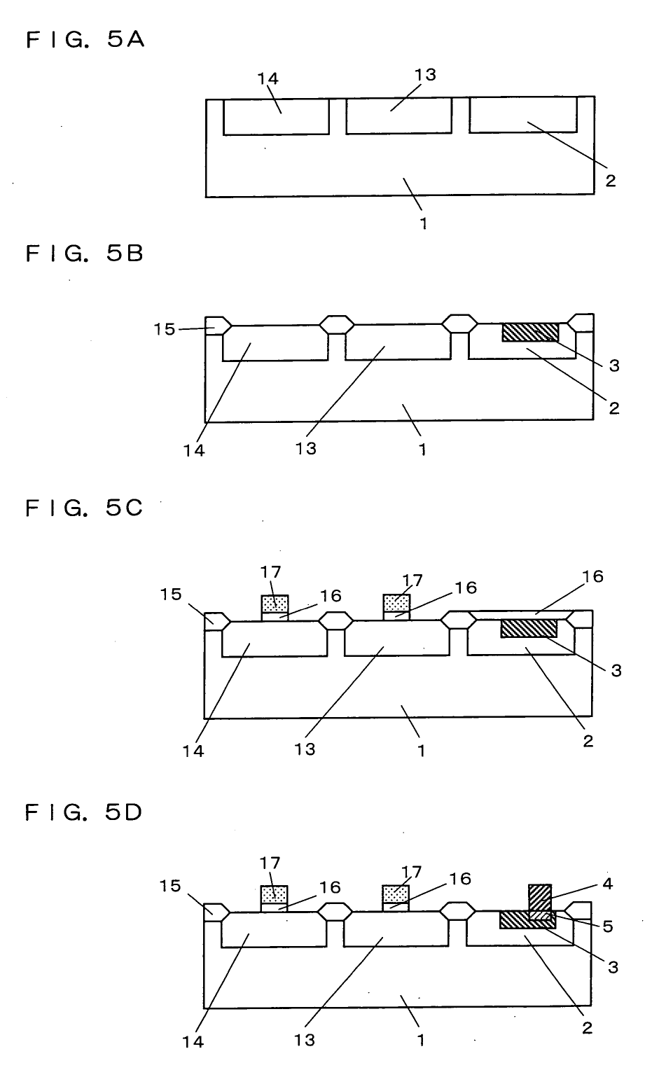

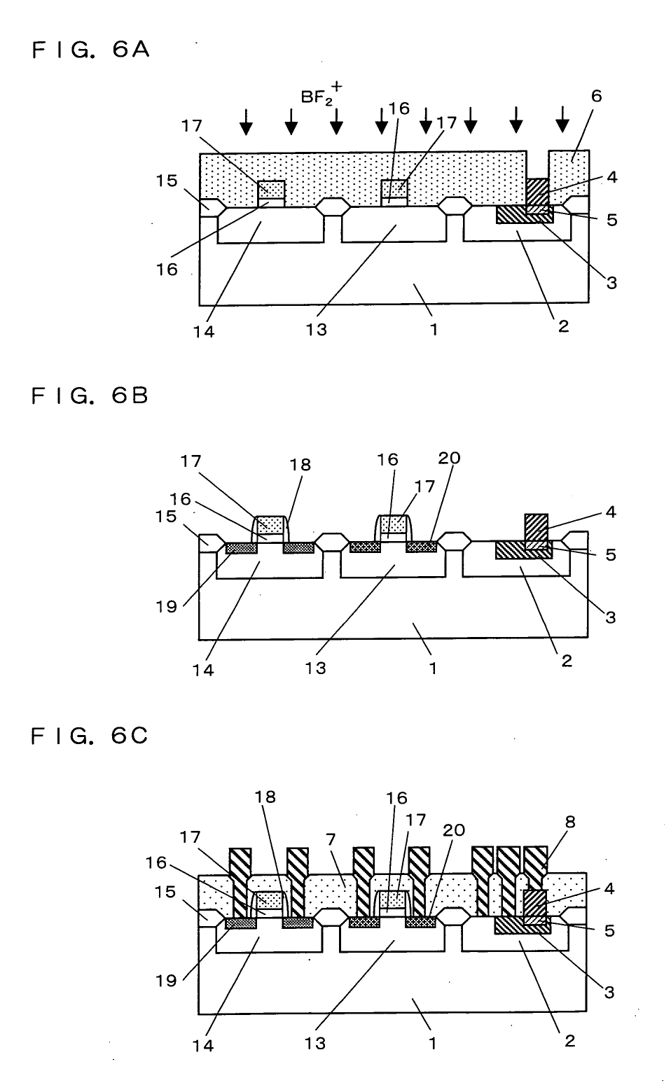

Next, respective steps in a method of manufacturing the semiconductor device having the BiCMOS structure according to the present embodiment are described referring to sectional views shown in FIGS. 5A-5D and 6A-6C.

First, as shown in FIG. 5A, the N-type well layer 13 and the P-type well layer 14 are respectively formed in the semiconductor substrate 1 having an N-type epitaxial layer on a surface there of by ion-implanting phosphorous and boron. The P-type collector diffusion layer 2 is formed at the same time as the formation of the P-type well layer 14.

Next, as shown in FIG. 5B, after the field oxide film 15 for determining the element region on the surface of the semiconductor substrate 1 is formed, phosphorous P⁺ is ion-implanted in the collector diffusion layer 2 at, for example, an accelerating energy of 45-55 keV and a dosage of 3-5×10¹³ cm⁻² so as to form the N-type base diffusion layer 3.

Next, as shown in FIG. 5C, after the gate oxide film 16 having a thickness of approximately 10-20 nm is formed on the surface of the semiconductor substrate 1, a first polycrystal silicon film having a thickness of 300-400 nm is grown, and phosphorous is ion-implanted therein. After that, the polycrystal silicon gate electrode 17 of the MOS transistor is formed at a predetermined position through the photo-resist patterning and dry etching.

Next, as shown in FIG. 5D, the gate oxide film 16 on the base diffusion layer 3 in the bipolar transistor region is etched to be thereby removed, and a second polycrystal silicon film having a thickness of approximately 200 nm is grown. Then, BF₂⁺ is ion-implanted at, for example, an acceleration energy of 25-35 keV and a dosage of 3-8×10¹⁵ cm⁻². After that, the polycrystal silicon emitter layer 4 including boron is formed at a predetermined position through the photo-resist patterning and dry etching, and thereafter, the heat treatment is applied at a temperature of, for example, 900-1000° C. so that the P-type emitter diffusion layer 5 is formed in the base diffusion layer 3 by diffusing the impurities from the polycrystal silicon emitter layer 4.

Next, as shown in FIG. 6A, a photo resist 6 is patternized, and BF₂⁺ is ion-implanted in the polycrystal silicon emitter layer 4 at, for example, an acceleration energy of 25-35 keV and a dosage of 3-8×10¹⁵ cm⁻².

Next, as shown in FIG. 6B, the side wall 18 is formed in a sidewall of the polycrystal silicon gate electrode 17 of the MOS transistor, and then, BF₂⁺ and arsenic are ion-implanted using the polycrystal silicon gate electrode 17 as a mask so that the source/drain diffusion layers 19 and 20 of the MOS transistor are respectively formed in the well layers 13 and 14. The source/drain diffusion layers 19 and 20 are subjected to the heat treatment at a temperature lower than the temperature at which the emitter diffusion layer 5 is formed (900-1000° C.), for example, in the range of 800-900° C. The heat treatment serves to activate boron additionally introduced into the polycrystal silicon emitter layer 4.

Next, as shown in FIG. 6C, the insulation film 7 is deposited, the contact holes are opened, and the wirings 8 are formed.

As described, according to the present embodiment, in addition to the effect achieved by the embodiment 1, the characteristics of the bipolar transistor and the MOS transistor can be determined independently from each other. Therefore, the characteristic of the MOS transistor can be prevented from deteriorating and the Early voltage and emitter/collector withstand voltage of the bipolar transistor can be prevented from lowering, while a high current amplification factor can be realized.

### Embodiment 3

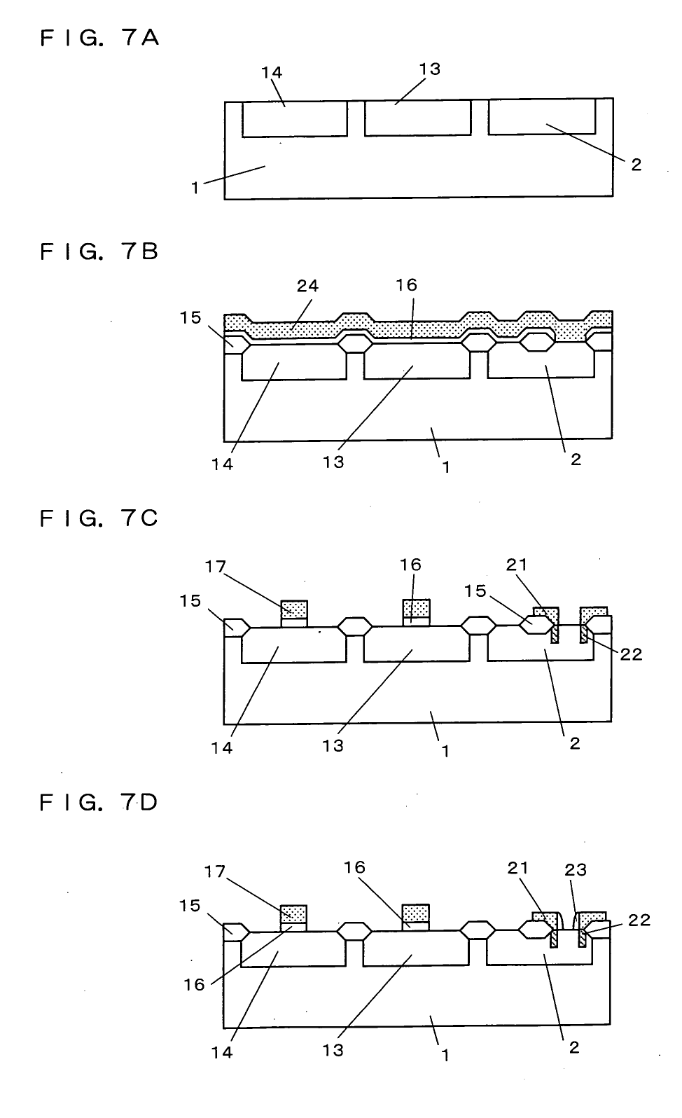

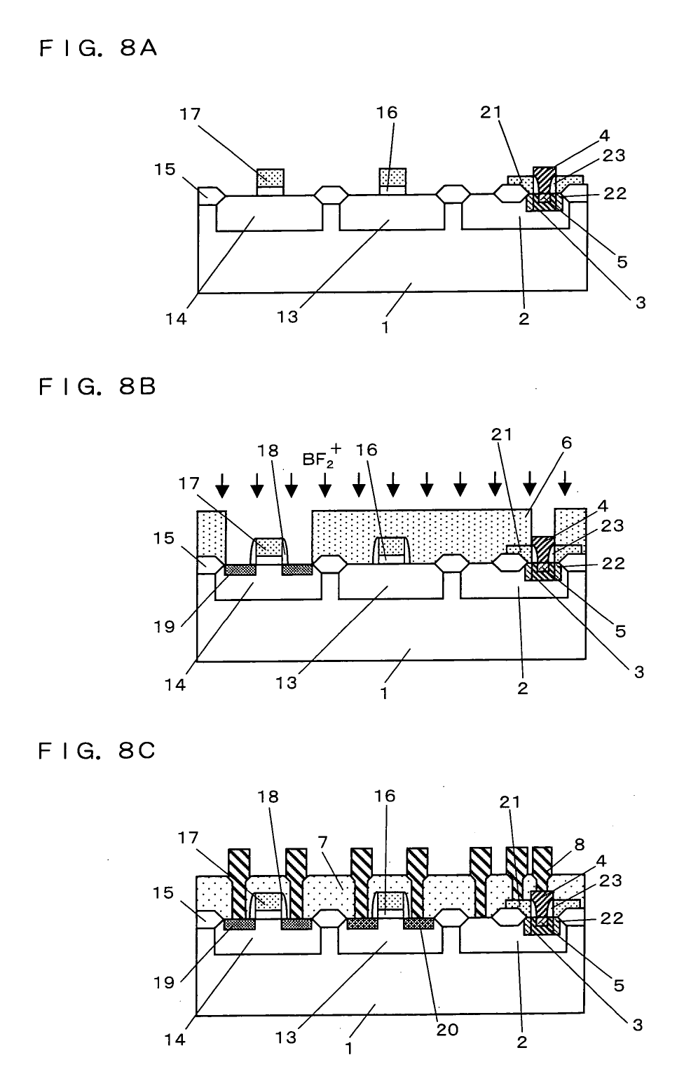

Respective steps in a method of manufacturing a semiconductor device of a BiCMOS structure having a PNP-type bipolar transistor and a CMOS transistor according to an embodiment 3 of the present invention are shown in sectional views of FIGS. 7A-7D and 8A-8C. The present embodiment is different to the embodiment 2 in that a polycrystal silicon gate electrode of the MOS transistor and a polycrystal silicon external base layer of the bipolar transistor are formed from the same polycrystal silicon.

First, as shown in FIG. 7A, an N-type well layer 13 and a P-type well layer 14 are respectively formed in a semiconductor substrate 1 having an N-type epitaxial layer on a surface thereof by ion-implanting phosphorous and boron. The P-type collector diffusion layer 2 is formed at the same time as the formation of the P-type well layer 14.

Next, as shown in FIG. 7B, a field oxide film 15 for determining the element region is formed on the surface of the semiconductor substrate 1, and then, a gate oxide film 16 having a thickness of 15-20 nm is formed. After that, the gate oxide film 16 of the bipolar transistor region is removed, and a first polycrystal silicon 24 having a thickness of 300-400 nm is grown on the entire surface of the substrate.

Next, as shown in FIG. 7c, phosphorous P⁺ is ion-implanted at, for example, an accelerating energy of 25-35 keV and a dosage of 3-8×10¹⁵ cm⁻². Thereafter, the photo-resist patterning process is implemented, and the first polycrystal silicon 24 is etched so that a polycrystal silicon gate electrode 17 of the MOS transistor and a polycrystal silicon external base layer 21 of the bipolar transistor are simultaneously formed. Accordingly, an impurity concentration of the polycrystal silicon external base layer 21 is equal to an impurity concentration of the polycrystal silicon gate electrode 17.

The polycrystal silicon external base layer 21 is formed on the collector diffusion layer 2 and the field oxide film 15 so as to have an opening in the emitter region. Thereafter, a thin oxide film (not shown) is formed on the surfaces of the semiconductor substrate 1, polycrystal silicon gate electrode 17 and polycrystal silicon external base layer 21 through thermal oxidation. The thermal oxidation serves to form the external base diffusion layer 22 of the bipolar transistor in the collector diffusion layer 2 excluding the emitter region with the polycrystal silicon external base layer 21 including phosphorous P as the diffusion source.

Next, as shown in FIG. 7D, the photo-resist patterning process is carried out, and phosphorous P⁺ is ion-implanted in the base region at, for example, an acceleration energy of 45-55 keV and a dosage of 3-5×10¹³ cm⁻². After that, a silicon nitriding film (not shown) is grown by approximately 40 nm, and a second polycrystal silicon film is grown by approximately 300 nm. As a result, a side wall 23 is formed in a sidewall of the polycrystal silicon external base layer 21.

Next, as shown in FIG. 8A, the photo-resist patterning process is carried out, and a third polycrystal silicon film having a thickness of approximately 200 nm is formed after the silicon nitriding film of the emitter region is removed. Then, BF₂⁺ is ion-implanted at, for example, an acceleration energy of 25-35 keV and a dosage of 3-10×10¹⁵ cm⁻². Next, the photo-resist patterning and dry etching are carried out so that the polycrystal silicon emitter layer 4 including boron is formed at a predetermined position. Thereafter, the heat treatment is performed at, for example, a high temperature in the range of 900-1100° C. and in a short period of time in the range of of 15-30 seconds by means of a lamp annealing treatment. As a result of the heat treatment, the N-type base diffusion layer 3 and the P-type emitter diffusion layer 5 are simultaneously formed.

Next, as shown in FIG. 8B, in the same manner as in the embodiment 2, a side wall 18 is formed in a sidewall of the polycrystal silicon gate electrode 17 of the MOS transistor, and source/drain diffusion layers 19 and 20 are respectively formed in the well layers 13 and 14. Boron is ion-implanted in the polycrystal silicon emitter layer 4 at the same as the ion implantation of BF₂⁺ for the formation of the P-type source/drain diffusion layer 20. In the foregoing manner, the additional introduction of boron with respect to the polycrystal silicon emitter layer 4 can also serve as the ion implantation for the formation of the source/drain diffusion layer 20, as a result of which the manufacturing process can be simplified. After that, the source/drain diffusion layers 19 and 20 are formed at a temperature lower than the heat-treatment temperature employed when the emitter diffusion layer 5 is formed (900-1100° C.), for example, in the range of 800-900° C. The heat treatment serves to activate boron additionally introduced into the polycrystal silicon emitter layer 4.

Next, as shown in FIG. 8C, an insulation film 7 is deposited, contact holes are opened, and wirings 8 are formed.

As described, according to the present embodiment, in the same manner as in the embodiment 2, the characteristics of the bipolar transistor and the MOS transistor can be determined independently from each other. Further, the polycrystal silicon external base layer 21 can be formed at the same time as the formation of the polycrystal silicon gate electrode 17 of the MOS transistor. In consequence of that, the high-performance bipolar transistor of the self-aligning type can be formed without undermining the characteristic of the MOS transistor. Moreover, the impurities can be additionally introduced into the polycrystal silicon emitter layer at the same time as the formation of the source/drain diffusion layer of the MOS transistor. As a result, the high-performance efficient bipolar transistor of the self-aligning type can be formed without increasing the manufacturing cost.

The present invention is not limited to the recited embodiments and can be variously modified and implemented within the scope of its technical idea.

The respective embodiments were described referring to the PNP-type bipolar transistor, however, it is needless to say that the present invention can exert the same effect in the case of applying the present invention to an NPN-type bipolar transistor.

As thus far described, according to the present invention, the high-performance semiconductor device capable of controlling the reduction of the base width and preventing the reduction of the Early voltage and emitter/collector withstand voltage while securing a high current amplification factor because of the impurity concentration of the polycrystal silicon emitter layer higher than the impurity concentration of the surface of the emitter diffusion layer can be realized.

1. A semiconductor device comprising:
a collector diffusion layer formed in a semiconductor substrate;
a base diffusion layer formed in the collector diffusion layer;
an emitter diffusion layer formed in the base diffusion layer; and
a polycrystal silicon emitter layer formed on the emitter diffusion layer and having an impurity concentration higher than an impurity concentration of a surface of the emitter diffusion layer.

2. A semiconductor device of a BiCMOS structure including a bipolar transistor and a MOS transistor, the bipolar transistor comprising:
a collector diffusion layer formed in a semiconductor substrate;
a base diffusion layer formed in the collector diffusion layer;
an emitter diffusion layer formed in the base diffusion layer; and
a polycrystal silicon emitter layer formed on the emitter diffusion layer and having an impurity concentration higher than an impurity concentration of a surface of the emitter diffusion layer, and
the CMOS transistor comprising:
a well layer formed in the semiconductor substrate;
a polycrystal silicon gate electrode formed on the well layer via a gate insulation film; and
a source/drain diffusion layer formed in the well layer, wherein
an emitter impurity concentration obtained by summing the impurity concentration of the polycrystal silicon emitter layer and the impurity concentration of the emitter diffusion layer is higher than an impurity concentration of the source/drain diffusion layer.

3. A semiconductor device as claimed in claim 1, wherein
the polycrystal silicon emitter layer is used as a diffusion source of impurities of the emitter diffusion layer.

4. A semiconductor device as claimed in claim 2, wherein
the polycrystal silicon emitter layer is used as a diffusion source of impurities of the emitter diffusion layer.

5. A semiconductor device as claimed in claim 2, wherein
the bipolar transistor further comprises an external base diffusion layer formed in a periphery of the base diffusion layer and a polycrystal silicon external base layer connected to the external base diffusion layer, and
an impurity concentration of the polycrystal silicon external base layer is equal to an impurity concentration of the polycrystal silicon gate electrode, and the polycrystal silicon external base layer is a diffusion source of impurities of the base diffusion layer.

6. A method of manufacturing a semiconductor device comprising:
a step of forming a collector diffusion layer in a semiconductor substrate;
a step of forming a base diffusion layer in the collector diffusion layer;
a step of forming a polycrystal silicon emitter layer serving as a diffusion source of impurities on the base diffusion layer;
a step of forming an emitter diffusion layer by diffusing the impurities of the polycrystal silicon emitter layer in the base diffusion layer; and
a step of additionally introducing the impurities into the polycrystal silicon emitter layer and applying a heat treatment to the impurities at a temperature lower than a diffusion temperature at which the emitter diffusion layer is formed to thereby activate the impurities.

7. A method of manufacturing a semiconductor device of a BiCMOS structure including a bipolar transistor and a MOS transistor comprising:
a step of forming a collector diffusion layer and a well layer in a semiconductor substrate;
a step of forming a polycrystal silicon gate electrode on the well layer via a gate insulation film;
a step of forming a base diffusion layer in the collector diffusion layer;
a step of forming a polycrystal silicon emitter layer serving as a diffusion source of impurities on the base diffusion layer;
a step of forming an emitter diffusion layer by diffusing the impurities of the polycrystal silicon emitter layer in the base diffusion layer;
a step of additionally introducing the impurities into the polycrystal silicon emitter layer;
a step of introducing the impurities into the well layer; and
a step of applying a heat treatment to the impurities at a temperature lower than a diffusion temperature at which the emitter diffusion layer is formed to thereby form a source/drain diffusion layer in the well layer and activate the impurities of the polycrystal silicon emitter layer.

8. A method of manufacturing a semiconductor device as claimed in claim 7, wherein
the step of additionally introducing the impurities into the polycrystal silicon emitter layer is carried out at the same time as the step of introducing the impurities into the well layer.

9. A method of manufacturing a semiconductor device as claimed in claim 7, wherein
a step of forming a field insulation film is further included prior to the formation of the polycrystal silicon gate electrode;
the step of forming the polycrystal silicon gate electrode includes a step of simultaneously forming a polycrystal silicon external base layer having an opening on the collector diffusion layer on the field insulation film and on the collector diffusion layer to thereby form an external base diffusion layer by diffusing the impurities of the polycrystal silicon external base layer in the collector diffusion layer after the formation of the polycrystal silicon external base layer, and
the base diffusion layer is formed in the collector diffusion layer via the opening in the step of forming the base diffusion layer.

10. A method of manufacturing a semiconductor device as claimed in claim 8, wherein
a step of forming a field insulation film is further included prior to the formation of the polycrystal silicon gate electrode;
the step of forming the polycrystal silicon gate electrode includes a step of simultaneously forming a polycrystal silicon external base layer having an opening on the collector diffusion layer on the field insulation film and on the collector diffusion layer to thereby form an external base diffusion layer by diffusing the impurities of the polycrystal silicon external base layer in the collector diffusion layer after the formation of the polycrystal silicon external base layer, and
the base diffusion layer is formed in the collector diffusion layer via the opening in the step of forming the base diffusion layer.

11. A method of manufacturing a semiconductor device as claimed in claim 6, wherein
the step of forming the emitter diffusion layer is carried out at a high temperature and in a short period of time by means of a lamp annealing treatment.

12. A method of manufacturing a semiconductor device as claimed in claim 7, wherein
the step of forming the emitter diffusion layer is carried out at a high temperature and in a short period of time by means of a lamp annealing treatment.

13. A method of manufacturing a semiconductor device as claimed in claim 8, wherein
the step of forming the emitter diffusion layer is carried out at a high temperature and in a short period of time by means of a lamp annealing treatment.

14. A method of manufacturing a semiconductor device as claimed in claim 9, wherein
the step of forming the emitter diffusion layer is carried out at a high temperature and in a short period of time by means of a lamp annealing treatment.

15. A method of manufacturing a semiconductor device as claimed in claim 10, wherein
the step of forming the emitter diffusion layer is carried out at a high temperature and in a short period of time by means of a lamp annealing treatment.
